(19) United States
(12) Patent Application Publication
(10) Pub. No.: US 2025/0105050 A1
(43) Pub. Date: Mar. 27, 2025

(54) CHUCK PIN AND SUBSTRATE HOLDING DEVICE

(71) Applicant: SCREEN Holdings Co., Ltd., Kyoto (JP)

(72) Inventors: Kazuma FUNAHASHI, Kyoto-shi (JP); Tomoyuki SHINOHARA, Kyoto-shi (JP)

(73) Assignee: SCREEN Holdings Co., Ltd., Kyoto (JP)

(21) Appl. No.: 18/884,122

(22) Filed: Sep. 13, 2024

(30) Foreign Application Priority Data
Sep. 25, 2023 (JP) 2023-159321

(51) Int. Cl. H01L 21/687

(52) U.S. Cl. CPC H01L 21/6875; H01L 21/68764; H01L 21/68785

(57) ABSTRACT

A chuck pin includes a holding portion and a fixing portion and holds a substrate. The holding portion has an inner circumferential surface and an outer circumferential surface capable of abutting against the substrate. The inner circumferential surface of the holding portion is formed with a protruding portion that protrudes inward. The fixing portion includes a pressing portion, a pressed portion, and an urging portion, and detachably fixes the holding portion. The pressing portion has a side wall portion in which a first opening portion is formed. The pressed portion has a side wall portion in which a second opening portion is formed. The urging portion urges the pressing portion in a rotation direction with respect to the pressed portion. The protruding portion formed on the inner circumferential surface of the holding portion is sandwiched between the pressing portion and the pressed portion at the first and second opening portions.

### CROSS-REFERENCE TO RELATED APPLICATION

This application claims the priority benefit of Japanese application serial no. 2023-159321, filed on Sep. 25, 2023. The entirety of the above-mentioned patent application is hereby incorporated by reference herein and made a part of this specification.

### BACKGROUND

### Technical Field

The disclosure relates to a chuck pin and a substrate holding device that hold a substrate.

### Description of Related Art

A substrate processing device is used to perform various processes on semiconductor substrates. In the substrate processing device, a plurality of chuck pins abut against the outer circumferential end portion of the substrate, thereby holding the substrate to be processed in a horizontal position. When the chuck pin is used for a long period of time, the portion of the chuck pin that comes into contact with the substrate wears out, making it impossible to accurately hold or release the substrate. Thus, the chuck pins are periodically replaced before they wear out.

Japanese Patent Application Laid-Open No. 2000-100706 describes a holding pin in which a pin member is supported by a pin support portion. The pin support portion is provided with a hole portion in which a spiral groove is formed on the inner circumferential surface. The pin member is formed with a protrusion that screws into the hole portion of the pin support portion. Thus, the pin member is fixed to the pin support portion by being turned in one direction, and is detached from the pin support portion by being turned in the opposite direction.

### SUMMARY

According to the holding pin disclosed in Japanese Patent Application Laid-Open No. 2000-100706, the replacing work of the pin member becomes easy. However, in order to prevent a decrease in productivity due to a drop in the availability rate of the substrate holding device accompanying part replacement and an increase in labor costs for replacement workers, a chuck pin that allows the holding portion to be replaced more easily is required.

The disclosure provides a chuck pin and a substrate holding device that allow easy replacement of a holding portion.

The chuck pin according to one aspect of the disclosure is configured to hold a substrate, including: a holding portion, having an inner circumferential surface and an outer circumferential surface capable of abutting against the substrate; and a fixing portion, detachably fixing the holding portion. The fixing portion includes: a pressing portion, having a first side wall portion in which a first opening portion is formed; a pressed portion, having a second side wall portion in which a second opening portion is formed; and an urging portion, urging the pressing portion in a first rotation direction with respect to the pressed portion. A protruding portion is formed on the inner circumferential surface of the holding portion, the protruding portion protruding inwardly and being sandwiched between the pressing portion and the pressed portion at the first opening portion and the second opening portion.

The substrate holding device according to another aspect of the disclosure includes the above-mentioned chuck pin and a plate portion to which the fixing portion of the chuck pin is mounted.

According to the disclosure, pin members may be easily replaced.

### BRIEF DESCRIPTION OF THE DRAWINGS

FIG. 1 is a schematic cross-sectional view of the substrate holding device according to the embodiment of the disclosure.

FIG. 2 is an exploded perspective view of the chuck pin.

FIG. 3 is an enlarged longitudinal sectional view of a portion of the chuck pin.

FIG. 4 is a perspective view of the fixing portion of the chuck pin.

FIG. 5 is a diagram illustrating the mounting operation of the holding portion by the arm portion.

FIG. 6 is a diagram illustrating the detaching operation of the holding portion by the arm portion.

### DESCRIPTION OF THE EMBODIMENTS

### 1. Substrate Holding Device

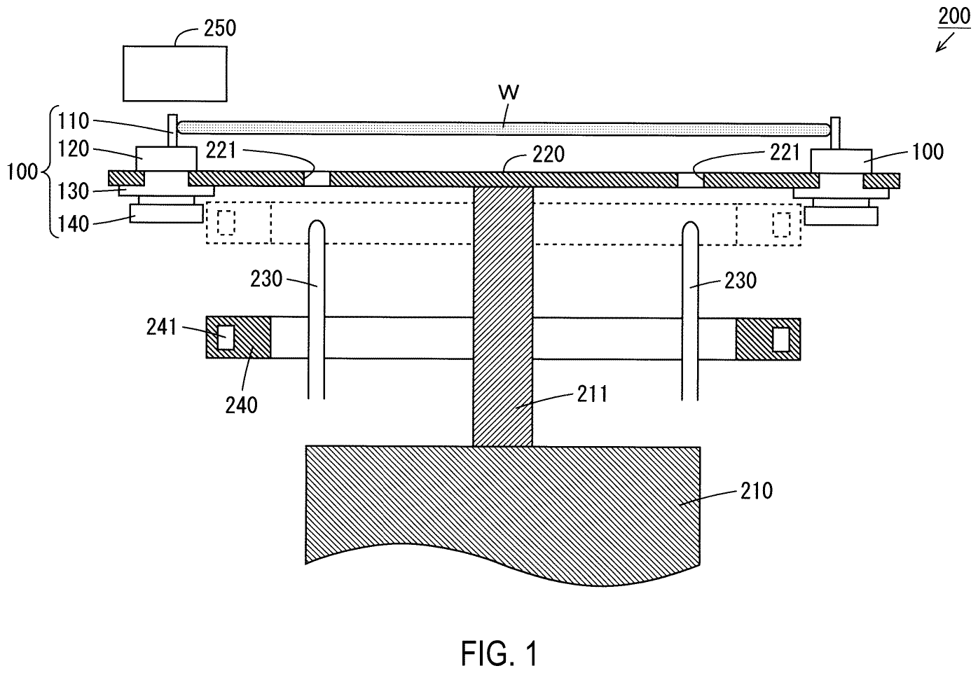

Hereinafter, a chuck pin and a substrate holding device according to the embodiment of the disclosure will be described with reference to the drawings. FIG. 1 is a schematic cross-sectional view of the substrate holding device according to the embodiment of the disclosure. As shown in FIG. 1, the substrate holding device 200 includes a plurality of chuck pins 100, a rotation driving portion 210, a plate portion 220, a plurality of supporting pins 230 (three in this example), a magnet supporting portion 240, and an arm portion 250.

In this example, the rotation driving portion 210 is provided at the bottom of the substrate holding device 200. The rotation driving portion 210 has a spin motor having a rotary shaft 211 extending upward. The plate portion 220 has a disk shape and is provided on the upper end portion of the rotary shaft 211 of the rotation driving portion 210 in a substantially horizontal position. The rotary shaft 211 is rotated by the rotation driving portion 210, whereby the plate portion 220 rotates about a vertical axis. In the plate portion 220, a plurality of through holes 221 are formed, each of which corresponds to a corresponding one of the supporting pins 230. The plurality of chuck pins 100 are provided on the periphery of the plate portion 220 at approximately equal angular intervals with respect to the rotary shaft 211.

Each chuck pin 100 includes a holding portion 110, a fixing portion 120, a mounting portion 130, and a turning driving portion 140. The holding portion 110 includes a pin member and is detachably fixed to the fixing portion 120. The arm portion 250 operates when the holding portion 110 is attached or detached. The chuck pin 100 and the arm portion 250 are described in detail later. The fixing portion 120 is mounted to the plate portion 220 by the mounting portion 130. The holding portion 110 protrudes above the plate portion 220 when fixed to the fixing portion 120.

The turning driving portion 140 includes a magnet and is fixed to the fixing portion 120 below the plate portion 220. The turning driving portion 140 turns the corresponding holding portion 110 between a holding state and a non-holding state. The holding state is a state in which the outer circumferential surface of the holding portion 110 abuts against the outer circumferential end portion of the substrate W. In the holding state, the substrate W is held by a plurality of holding portions 110. The non-holding state is a state in which the holding portion 110 is not in contact with the substrate W and is separated from the substrate W. In the non-holding state, the substrate W is released from the plurality of holding portions 110.

The plurality of supporting pins 230 are provided to extend upward and surround the rotary shaft 211 of the rotation driving portion 210. Each supporting pin 230 is raised and lowered between a standby position and a transfer position by an actuator (not shown). In the standby position, the upper end portion of each supporting pin 230 is lower than the plate portion 220. In the transfer position, each supporting pin 230 is inserted into the corresponding through hole 221 of the plate portion 220, so that the upper end portion of each supporting pin 230 is at substantially the same height as the holding portion 110 of the chuck pin 100. Each supporting pin 230 is raised to a transfer position when the substrate W is transferred between a substrate transport device (not shown) and the substrate holding device 200, and at other times, the supporting pin 230 is lowered to a standby position.

The magnet supporting portion 240 has an annular shape and surrounds the rotary shaft 211 and the plurality of supporting pins 230 of the substrate holding device 200. The magnet supporting portion 240 supports an annular-shaped magnet 241, and is raised and lowered between a holding position and a non-holding position by an actuator (not shown). The holding position is at approximately the same height as the turning driving portion 140 of the chuck pin 100. The non-holding position is below the holding position. As shown by the dotted line in FIG. 1, when the magnet supporting portion 240 is raised to the holding position, the magnet 241 approaches the magnet of the turning driving portion 140, causing the holding portion 110 to turn to the holding state. When the magnet supporting portion 240 is lowered to the non-holding position, the magnet 241 moves away from the magnet of the turning driving portion 140, causing the holding portion 110 to turn to the non-holding state.

### 2. Chuck Pin

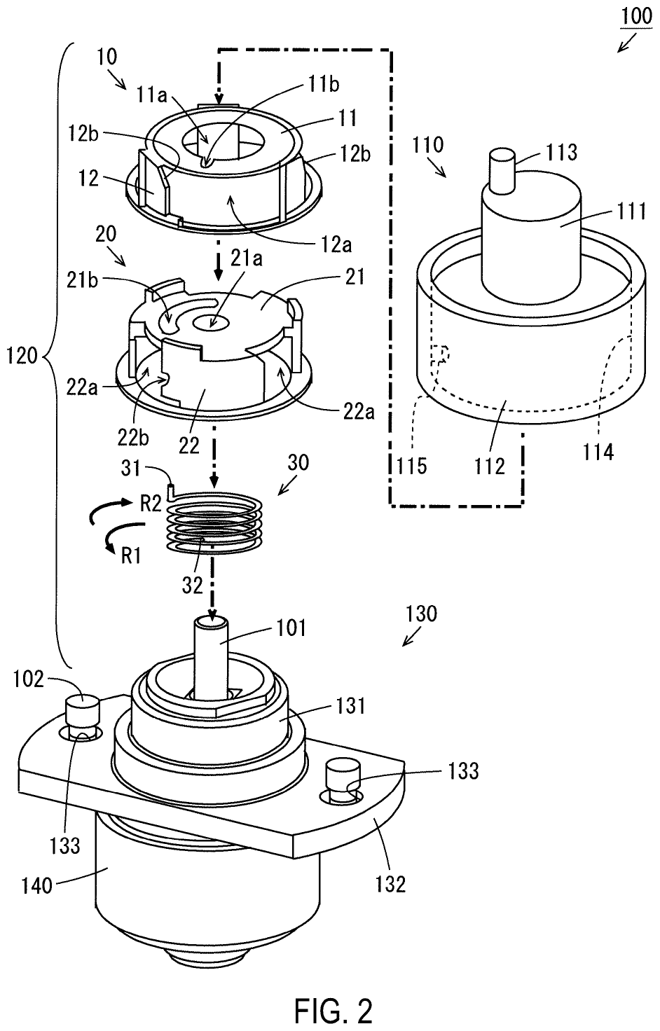

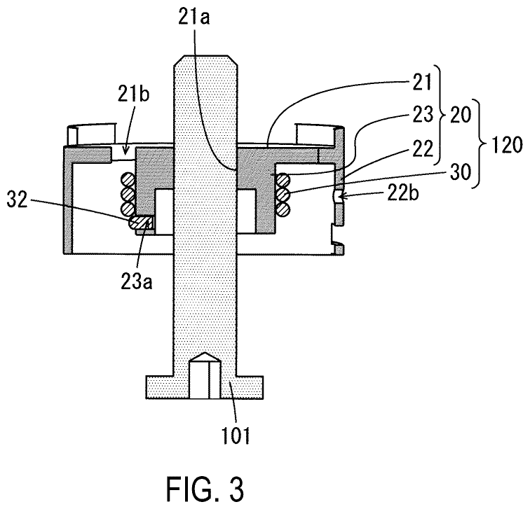

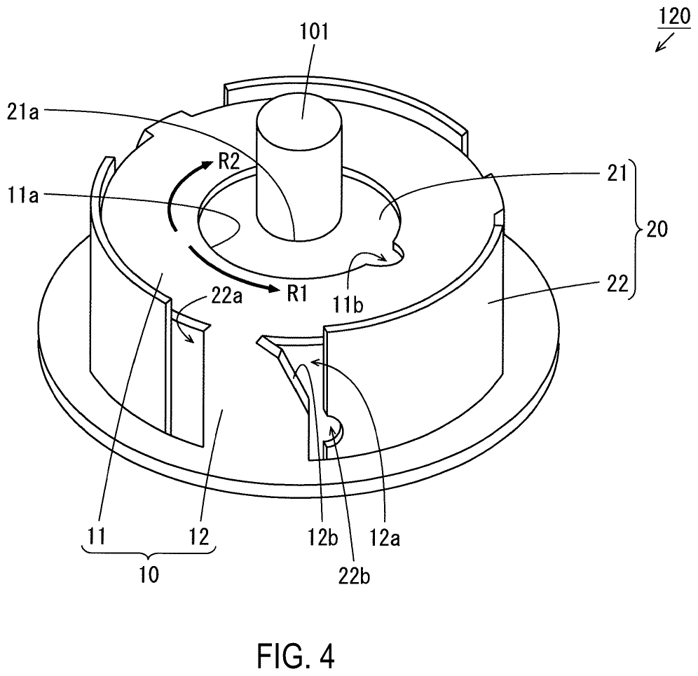

FIG. 2 is an exploded perspective view of the chuck pin 100. FIG. 3 is an enlarged longitudinal sectional view of a portion of the chuck pin 100. FIG. 4 is a perspective view of the fixing portion 120 of the chuck pin 100. As shown in FIG. 2, the chuck pin 100 includes a holding portion 110, a fixing portion 120, a mounting portion 130, and a turning driving portion 140.

The holding portion 110 includes a pin member 111 and a base portion 112. The pin member 111 protrudes upward from an upper portion of the base portion 112. The pin member 111 has an outer circumferential surface 113, at the upper portion, capable of abutting against the substrate W. The base portion 112 has a cylindrical shape with the upper portion closed. The base portion 112 is fixed to the fixing portion 120 so as to cover the fixing portion 120. An inner circumferential surface 114 of the base portion 112 is formed with a protruding portion 115 that protrudes inward. In this example, three protruding portions 115 are formed on the inner circumferential surface 114 of the base portion 112 at intervals of 120 degrees in the circumferential direction.

The fixing portion 120 includes a pressing portion 10, a pressed portion 20, an urging portion 30, and a support member (not shown). The pressing portion 10 has a main surface portion 11 and a side wall portion 12. The main surface portion 11 has a disk shape. In the center portion of the main surface portion 11, a circular opening portion 11a is formed. Further, in the main surface portion 11, a hole portion 11b is formed. In this example, the hole portion 11b is formed in a notch shape so as to be continuous with the opening portion 11a, but the embodiment is not limited thereto.

The side wall portion 12 is bent so as to extend downward from the outer edge portion of the main surface portion 11. In the side wall portion 12, an opening portion 12a is formed. In this example, three opening portions 12a are formed in the side wall portion 12 at intervals of 120 degrees in the circumferential direction. The opening portions 12a indicate portions recessed toward the center of the side wall portion 12 when the side wall portion 12 is viewed in a plan view. The three opening portions 12a of the side wall portion 12 correspond to the three protruding portions 115 of the holding portion 110, respectively. Further, the cut end of the side wall portion 12 where each opening portion 12a is formed has a tapered surface 12b.

The pressed portion 20 has a main surface portion 21, a side wall portion 22, and a side wall portion 23 (FIG. 3). The main surface portion 21 has a disk shape. A screw hole 21a is formed in the center portion of the main surface portion 21. Further, the main surface portion 21 is formed with a slit 21b extending parallel to a rotation direction R1, which is described later.

The side wall portion 22 is formed so as to extend downward and partially upward from the outer edge portion of the main surface portion 21. In the side wall portion 22, an opening portion 22a is formed. In this example, three opening portions 22a are formed in the side wall portion 22 at intervals of 120 degrees in the circumferential direction. The three opening portions 22a of the side wall portion 22 correspond to the three protruding portions 115 of the holding portion 110, respectively. Further, the cut end of the side wall portion 22 where each opening portion 22a is formed has a recessed portion 22b. As shown in FIG. 3, the side wall portion 23 extends downward from the main surface portion 21 on the inside of the side wall portion 22. In the side wall portion 23, a hole portion 23a is formed.

As shown in FIG. 4, the pressing portion 10 is provided so as to cover the pressed portion 20. In this state, the side wall portion 22 of the pressed portion 20 is exposed from the opening portion 12a of the side wall portion 12 of the pressing portion 10. As a result, the cut end of the side wall portion 12 where the opening portion 12a is formed faces the cut end of the side wall portion 22 where the opening portion 22a is formed. The tapered surface 12b of the side wall portion 12 is formed so as to gradually approach the recessed portion 22b of the side wall portion 22 toward the rotation direction R1.

As shown in FIG. 2, the urging portion 30 is, for example, a torsion spring wound around an axis parallel to the up and down direction, and has end portions 31 and 32. The end portion 31 is located at the upper end of the urging portion 30 and is bent upward. The end portion 32 is located at the lower end of the urging portion 30 and is bent inward. The urging portion 30 generates an urging force in a predetermined rotation direction. Hereinafter, the direction in which the urging portion 30 generates an urging force is referred to as a rotation direction R1, and the opposite direction is referred to as a rotation direction R2. In FIG. 2 and FIG. 4, the rotation directions R1 and R2 are indicated by thick arrows. The rotation direction R1 may be the same as the rotation direction of the plate portion 220 by the rotation driving portion 210 in FIG. 1, or may be opposite to the rotation direction of the plate portion 220.

As shown in FIG. 3, the urging portion 30 is provided between the side wall portion 22 and the side wall portion 23 of the pressed portion 20. In this example, the urging portion 30 is provided between the side wall portion 22 and the side wall portion 23 with a force being applied in the rotation direction R2, and the end portion 32 is fitted into the hole portion 23a of the side wall portion 23. Here, the force of the rotation direction R2 on the urging portion 30 is released, and the urging portion 30 is wound around the outer surface of the side wall portion 23 with the end 32 fitted into the hole portion 23a of the side wall portion 23. The end portion 31 of the urging portion 30 is fitted into the hole portion 11b of the main surface portion 11 of the pressing portion 10 in FIG. 2 with the end portion 31 inserted into the slit 21b of the main surface portion 21 of the pressed portion 20.

In this configuration, the pressing portion 10 is urged by the urging portion 30 in the rotation direction R1 with respect to the pressed portion 20. Thus, the fixing portion 120 is covered by the base portion 112 of the holding portion 110, so that the protruding portion 115 of the base portion 112 is sandwiched between the pressing portion 10 and the pressed portion 20 at the opening portion 12a and the opening portion 22a. As a result, the holding portion 110 is fixed to the fixing portion 120. In this example, each protruding portion 115 is guided along the tapered surface 12b of the pressing portion 10 to the corresponding recessed portion 22b of the pressed portion 20 and abuts against the recessed portion 22b. Thus, the holding portion 110 is fixed more stably.

A support member (not shown) is provided below the pressed portion 20. In this state, a bolt 101 is inserted into the support member from below. The tip of the bolt 101 protrudes from the support member and is screwed into the screw hole 21a of the main surface portion 21 of the pressed portion 20. As a result, the pressed portion 20 is supported by the support member. It is noted that as shown in FIG. 4, the tip of the bolt 101 screwed into the screw hole 21a protrudes upward through the opening portion 11a of the pressing portion 10.

As shown in FIG. 2, the mounting portion 130 has a cylindrical portion 131 and a base portion 132. The cylindrical portion 131 has a substantially cylindrical shape and extends in the up and down direction so as to be inserted into the plate portion 220 in FIG. 1. The base portion 132 has a generally oval shape and extends outward from the lower end portion of the cylindrical portion 131 below the plate portion 220. Two through holes 133 are formed on the base portion 132 opposite each other with the cylindrical portion 131 therebetween. A screw 102 is inserted into each through hole 133 from below and is screwed into a screw hole (not shown) on the lower surface of the plate portion 220. As a result, the mounting portion 130 is fixed to the plate portion 220.

In this example, a ball bearing (not shown) is provided that has a plurality of rolling members, an inner ring, and an outer ring. The plurality of rolling members are held between the inner ring and the outer ring by a holding tool (retainer). The inner ring is fitted onto the outer circumferential surface of the support member (not shown) of the fixing portion 120. Moreover, the outer ring is fitted into the inner circumferential surface of the cylindrical portion 131 of the mounting portion 130. As a result, the fixing portion 120 is mounted to the mounting portion 130 so as to be capable of turning around the central axis of the ball bearing.

The turning driving portion 140 is mounted to the lower end portion of the support member of the fixing portion 120. The turning driving portion 140 turns the holding portion 110 together with the fixing portion 120 between a holding state and a non-holding state in accordance with the operation of the magnet supporting portion 240 in FIG. 1.

### 3. Arm Portion

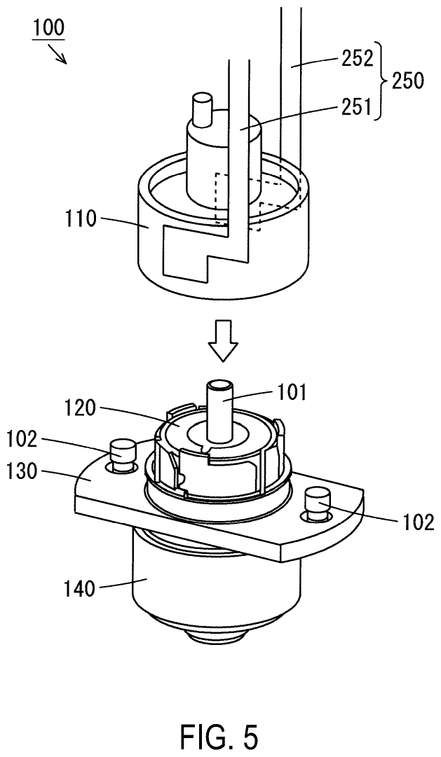

FIG. 5 is a diagram illustrating the mounting operation of the holding portion 110 by the arm portion 250. As shown in FIG. 5, the arm portion 250 includes a pair of fingers 251 and 252. When the holding portion 110 is mounted, the arm portion 250 moves above the fixing portion 120 while gripping the holding portion 110 with the fingers 251 and 252. In this state, the arm portion 250 is lowered as shown by the void arrow in FIG. 5. In this case, the holding portion 110 held by the fingers 251 and 252 is pushed into the fixing portion 120.

Here, by pushing the holding portion 110 into the fixing portion 120, the pressing portion 10 in FIG. 2 rotates in the rotation direction R2 against the urging force of the urging portion 30, and the protruding portion 115 of the holding portion 110 enters the opening portion 12a of the pressing portion 10 and the opening portion 22a of the pressed portion 20. Next, when the fingers 251 and 252 release the holding portion 110, the pressing portion 10 is urged by the urging portion 30 to rotate in the rotation direction R1, so that the protruding portion 115 of the holding portion 110 is sandwiched between the pressing portion 10 and the pressed portion 20 at the opening portion 12a and the opening portion 22a. As a result, the holding portion 110 is mounted to the fixing portion 120.

Thereafter, the arm portion 250 grips another holding portion 110 with the fingers 251 and 252 and repeats the same mounting operation for another fixing portion 120. As a result, the holding portions 110 are mounted to all of the fixing portions 120. In addition, in a series of mounting operations of the plurality of holding portions 110, the arm portion 250 may be moved sequentially above the plurality of fixing portions 120, and the plate portion 220 in FIG. 1 may be rotated so that the plurality of fixing portions 120 move sequentially below the arm portion 250.

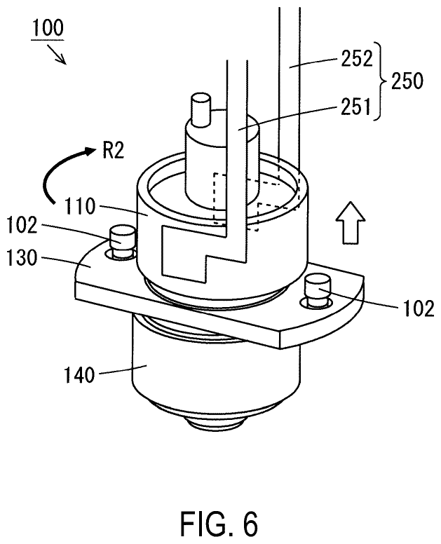

FIG. 6 is a diagram illustrating the detaching operation of the holding portion 110 by the arm portion 250. As shown in FIG. 6, when detaching the holding portion 110, the arm portion 250 moves above the fixing portion 120 and grips the holding portion 110 fixed to the fixing portion 120 with the fingers 251 and 252. In this state, the arm portion 250 rotates in the rotation direction R2 and is raised as shown by the void arrow in FIG. 6. In this case, the holding portion 110 is pulled out from the fixing portion 120 while being twisted in the rotation direction R2. As a result, the holding portion 110 is detached from the fixing portion 120.

Thereafter, the arm portion 250 grips another holding portion 110 with the fingers 251 and 252 and repeats the same detaching operation for another fixing portion 120. As a result, the holding portions 110 are detached from all of the fixing portions 120. In addition, in a series of detaching operations of the plurality of holding portions 110, the arm portion 250 may be moved sequentially above the plurality of fixing portions 120, and the plate portion 220 in FIG. 1 may be rotated so that the plurality of fixing portions 120 move sequentially below the arm portion 250.

### 4. Effect

In the chuck pin 100 according to this embodiment, when mounting the holding portion 110, by pushing the holding portion 110 into the fixing portion 120, the pressing portion 10 of the fixing portion 120 rotates in the rotation direction R2 against the urging force of the urging portion 30, and the protruding portion 115 of the holding portion 110 enters the opening portion 12a of the pressing portion 10 and the opening portion 22a of the pressed portion 20. In this state, the pressing portion 10 is urged by the urging portion 30 to rotate in the rotation direction R1, so that the protruding portion 115 of the holding portion 110 is sandwiched between the pressing portion 10 and the pressed portion 20 at the opening portion 12a and the opening portion 22a. As a result, the holding portion 110 may be mounted to the fixing portion 120.

On the other hand, when detaching the holding portion 110, the holding portion 110 is pulled out from the fixing portion 120 while being twisted in the rotation direction R2. As a result, the holding portion 110 may be detached from the fixing portion 120. In this way, the holding portion 110 may be mounted to and detached from the fixing portion 120 with a simple operation. As a result, the holding portion 110 may be easily replaced.

The side wall portion 22 of the pressed portion 20 is exposed from the opening portion 12a of the pressing portion 10. In this case, the holding portion 110 may be fixed to the fixing portion 120 with a simple configuration without increasing the size of the chuck pin 100.

In the pressed portion 20, the cut end of the side wall portion 22 where the opening portion 22a is formed has a recessed portion 22b that abuts against the protruding portion 115 of the holding portion 110. In this case, the holding portion 110 may be fixed more stably.

In the pressing portion 10, the cut end of the side wall portion 12 where the opening portion 12a is formed has a tapered surface 12b that gradually approaches the recessed portion 22b of the pressed portion 20 toward the rotation direction R1. In this case, when mounting the holding portion 110, it becomes easy to rotate the pressing portion 10 in the rotation direction R2 and to guide the protruding portion 115 of the holding portion 110 to the recessed portion 22b of the pressed portion 20.

The urging portion 30 has an end portion 31. The pressing portion 10 has a main surface portion 11 in which a hole portion 11b into which the end portion 31 of the urging portion 30 is fitted is formed. The pressed portion 20 has a main surface portion 21 which extends parallel to the rotation direction R1 and has a slit 21b through which the end portion 31 of the urging portion 30 is inserted. In this case, the pressing portion 10 may be easily rotated without rotating the pressed portion 20.

The pressed portion 20 has a side wall portion 23 formed inwardly of the side wall portion 22. The urging portion 30 is provided between the side wall portion 22 and the side wall portion 23 of the pressed portion 20. In this case, the urging portion 30 may be accommodated compactly.

The urging portion 30 has an end portion 32. A hole portion 23a into which the end portion 32 of the urging portion 30 is fitted is formed in the side wall portion 23 of the pressed portion 20. In this case, the urging portion 30 may be easily fixed.

The chuck pin 100 includes a turning driving portion 140 that turns the holding portion 110 and the fixing portion 120 between a holding state, in which the substrate W is held by abutting the outer circumferential surface 113 of the holding portion 110 against the substrate W, and a non-holding state, in which the substrate W is not held by separating the outer circumferential surface 113 of the holding portion 110 from the substrate W. In this case, the chuck pin 100 may be used as a rotary pin.

The substrate holding device 200 includes a chuck pin 100 and a plate portion 220 to which the fixing portion 120 of the chuck pin 100 is mounted. In this case, since the above-mentioned chuck pin 100 is used, the holding portion 110 may be easily replaced. The substrate holding device 200 further includes the rotation driving portion 210 that rotates the plate portion 220. In this case, the substrate W may be processed while being rotated.

Furthermore, the substrate holding device 200 includes an arm portion 250 that pushes the holding portion 110 into the fixing portion 120 while gripping the holding portion 110 of the chuck pin 100, and twists the holding portion 110 in the rotation direction R2 and pulls out the holding portion 110 from the fixing portion 120 while gripping the holding portion 110 of the chuck pin 100. In this case, the holding portion 110 is automatically mounted to the fixing portion 120 by the arm portion 250. In addition, the arm portion 250 automatically detaches the holding portion 110 from the fixing portion 120. As a result, manpower may be saved when replacing the holding portion 110.

### 5. Other Embodiments

(1) In the above embodiment, the chuck pin 100 is a rotary chuck pin in which the holding portion 110 turns between a holding state and a non-holding state, but the embodiment is not limited thereto. At least a portion of the chuck pins 100 provided on the substrate holding device 200 may be fixed chuck pins. In this case, the holding portion 110 does not need to include the turning driving portion 140.

(2) In the above embodiment, the substrate holding device 200 holds the outer circumferential end portion of the substrate W from below, but the embodiment is not limited thereto. The substrate holding device 200 may hold the outer circumferential end portion of the substrate W from above. In this case, each chuck pin 100 is provided so that the holding portion 110 protrudes below the plate portion 220.

(3) In the above embodiment, the tapered surface 12b is formed in the side wall portion 12 of the pressing portion 10, and the recessed portion 22b is formed in the side wall portion 22 of the pressed portion 20, but the embodiment is not limited thereto. When the holding portion 110 is stably fixed to the fixing portion 120, the tapered surface 12b may not be formed in the side wall portion 12 of the pressing portion 10, and the recessed portion 22b may not be formed in the side wall portion 22 of the pressed portion 20.

(4) In the above embodiment, the arm portion 250 performs both mounting and detaching of the holding portion 110, but the embodiment is not limited thereto. The arm portion 250 may only perform one of mounting and detaching the holding portion 110. Alternatively, the arm portion 250 for mounting the holding portion 110 and the arm portion 250 for detaching the holding portion 110 may be provided separately.

(5) In the above embodiment, the substrate holding device 200 includes the rotation driving portion 210 and the arm portion 250, but the embodiment is not limited thereto. When there is no need to rotate the plate portion 220, the substrate holding device 200 may not include the rotation driving portion 210. Further, when the replacement of the holding portion 110 of the chuck pin 100 is performed manually by a user, the substrate holding device 200 may not include the arm portion 250.

6. Correspondence between each element of the claims and each part of the embodiment Below, examples of correspondence between each element of the claims and each element of the embodiment are described, but the disclosure is not limited to the following examples. As each element of the claim, various other elements having the configuration or function described in the claim may be used.

In the above embodiment, the substrate W is an example of the substrate, the chuck pin 100 is an example of the chuck pin, the inner circumferential surface 114 is an example of the inner circumferential surface, the outer circumferential surface 113 is an example of the outer circumferential surface, the holding portion 110 is an example of the holding portion, and the fixing portion 120 is an example of the fixing portion. The opening portions 12a and 22a are examples of the first and second opening portions, respectively, the side wall portions 12, 22, and 23 are examples of the first, second, and third side wall portions, respectively, the pressing portion 10 is an example of the pressing portion, and the pressed portion 20 is an example of the pressed portion.

The rotation directions R1 and R2 are examples of the first and second rotation directions, respectively, the urging portion 30 is an example of the urging portion, the protruding portion 115 is an example of the protruding portion, the recessed portion 22b is an example of the recessed portion, and the tapered surface 12b is an example of the tapered surface. The end portions 31 and 32 are examples of the first and second end portions, respectively, the hole portions 11b and 23a are examples of the first and second hole portions, respectively, the main surface portions 11 and 21 are examples of the first and second main surface portions, respectively, and the slit 21b is an example of the slit. The turning driving portion 140 is an example of the turning driving portion, the plate portion 220 is an example of the plate portion, the substrate holding device 200 is an example of the substrate holding device, the rotation driving portion 210 is an example of the rotation driving portion, and the arm portion 250 is an example of the arm portion.

### 7. Summary of the Embodiment

(Configuration 1) A chuck pin in according to Configuration 1 is
a chuck pin, configured to hold a substrate, including:
a holding portion, having an inner circumferential surface and an outer circumferential surface capable of abutting against the substrate; and
a fixing portion, detachably fixing the holding portion,
wherein the fixing portion includes:
   a pressing portion, having a first side wall portion in which a first opening portion is formed;
   a pressed portion, having a second side wall portion in which a second opening portion is formed; and
   an urging portion, urging the pressing portion in a first rotation direction with respect to the pressed portion, and
   a protruding portion is formed on the inner circumferential surface of the holding portion, the protruding portion protruding inwardly and being sandwiched between the pressing portion and the pressed portion at the first opening portion and the second opening portion.

In this chuck pin, when mounting the holding portion, by pushing the holding portion into the fixing portion, the pressing portion of the fixing portion rotates in a direction opposite to the first rotation direction against the urging force of the urging portion, and the protruding portion of the holding portion enters the first opening portion of the pressing portion and the second opening portion of the pressed portion. In this state, the pressing portion is urged by the urging portion to rotate in the first rotation direction, so that the protruding portion of the holding portion is sandwiched between the pressing portion and the pressed portion at the first opening portion and the second opening portion. As a result, the holding portion may be mounted to the fixing portion.

On the other hand, when detaching the holding portion, the holding portion is pulled out from the fixing portion while being twisted in the direction opposite to the first rotation direction. As a result, the holding portion may be detached from the fixing portion. In this way, the holding portion may be mounted to and detached from the fixing portion with a simple operation. As a result, the holding portion may be easily replaced.

(Configuration 2) In the chuck pin according to Configuration 1,
the second side wall portion of the pressed portion may be exposed from the first opening portion of the pressing portion.

In this case, the holding portion may be fixed to the fixing portion with a simple configuration without increasing the size of the chuck pin.

(Configuration 3) In the chuck pin according to Configuration 1 or Configuration 2,
a cut end of the second side wall portion in the pressed portion where the second opening portion is formed may have a recessed portion that abuts against the protruding portion of the holding portion.

In this case, since the protruding portion of the holding portion abuts against the recessed portion of the pressed portion, the holding portion may be fixed more stably.

(Configuration 4) In the chuck pin according to Configuration 3, a cut end of the first side wall portion in the pressing portion where the first opening portion is formed may have a tapered surface that gradually approaches the recessed portion of the pressed portion toward the first rotation direction.

In this case, when mounting the holding portion, it becomes easy to rotate the pressing portion in the direction opposite to the first rotation direction and to guide the protruding portion of the holding portion to the recessed portion of the pressed portion.

(Configuration 5) In the chuck pin according to any one of Configuration 1 to Configuration 4,
the urging portion may have a first end portion,
the pressing portion may further include a first main surface portion formed with a first hole portion into which the first end portion of the urging portion is fitted, and
the pressed portion may further include a second main surface portion extending parallel to the first rotation direction and formed with a slit through which the first end portion of the urging portion is inserted.

In this case, the pressing portion may be easily rotated without rotating the pressed portion.

(Configuration 6) In the chuck pin according to any one of Configuration 1 to Configuration 5,
the pressed portion may further include a third side wall portion formed inwardly of the second side wall portion, and
the urging portion may be provided between the second side wall portion and the third side wall portion of the pressed portion.

In this case, the urging portion may be accommodated compactly.

(Configuration 7) In the chuck pin according to Configuration 6,
the urging portion may have a second end portion, and
a second hole portion into which the second end portion of the urging portion is fitted may be formed in the third side wall portion of the pressed portion.

In this case, the urging portion may be easily fixed.

(Configuration 8) The chuck pin according to any one of Configuration 1 to Configuration 7 may include
a turning driving portion, configured to turn the holding portion and the fixing portion between a holding state, in which the substrate is held by abutting the outer circumferential surface of the holding portion against the substrate, and a non-holding state, in which the substrate is not held by separating the outer circumferential surface of the holding portion from the substrate.

In this case, the chuck pin may be used as a rotary pin.

(Configuration 9) A substrate holding device according to Configuration 9 includes
the chuck pin according to any one of Configuration 1 to Configuration 8, and
a plate portion to which the fixing portion of the chuck pin is mounted.

In this case, since the above-mentioned chuck pin is used, the holding portion may be easily replaced.

(Configuration 10) The substrate holding device according to Configuration 9 may further include
a rotation driving portion configured to rotate the plate portion.

In this case, the substrate may be processed while being rotated.

(Configuration 11) The substrate holding device according to Configuration 9 or Configuration 10 may further include
a first arm portion configured to push the holding portion into the fixing portion while gripping the holding portion of the chuck pin.

In this case, the holding portion is automatically mounted to the fixing portion by the arm portion. As a result, manpower may be saved when replacing the holding portion.

(Configuration 12) The substrate holding device according to any one of Configuration 9 to Configuration 11 may further include
a second arm portion configured to twist the holding portion in a second rotation direction opposite to the first rotation direction and pull out the holding portion from the fixing portion while gripping the holding portion of the chuck pin.

In this case, the arm portion automatically detaches the holding portion from the fixing portion. As a result, manpower may be saved when replacing the holding portion.

What is claimed is:

1. A chuck pin, configured to hold a substrate, comprising:
a holding portion, having an inner circumferential surface and an outer circumferential surface capable of abutting against the substrate; and
a fixing portion, detachably fixing the holding portion,
wherein the fixing portion comprises:
a pressing portion, having a first side wall portion in which a first opening portion is formed;
a pressed portion, having a second side wall portion in which a second opening portion is formed; and
an urging portion, urging the pressing portion in a first rotation direction with respect to the pressed portion, and
a protruding portion is formed on the inner circumferential surface of the holding portion, the protruding portion protruding inwardly and being sandwiched between the pressing portion and the pressed portion at the first opening portion and the second opening portion.

2. The chuck pin according to claim 1, wherein the second side wall portion of the pressed portion is exposed from the first opening portion of the pressing portion.

3. The chuck pin according to claim 1, wherein a cut end of the second side wall portion in the pressed portion where the second opening portion is formed has a recessed portion that abuts against the protruding portion of the holding portion.

4. The chuck pin according to claim 3, wherein a cut end of the first side wall portion in the pressing portion where the first opening portion is formed has a tapered surface that gradually approaches the recessed portion of the pressed portion toward the first rotation direction.

5. The chuck pin according to claim 1, wherein the urging portion has a first end portion,
the pressing portion further comprises a first main surface portion formed with a first hole portion into which the first end portion of the urging portion is fitted, and
the pressed portion further comprises a second main surface portion extending parallel to the first rotation direction and formed with a slit through which the first end portion of the urging portion is inserted.

6. The chuck pin according to claim 1, wherein the pressed portion further comprises a third side wall portion formed inwardly of the second side wall portion, and
the urging portion is provided between the second side wall portion and the third side wall portion of the pressed portion.

7. The chuck pin according to claim 6, wherein the urging portion has a second end portion, and
a second hole portion into which the second end portion of the urging portion is fitted is formed in the third side wall portion of the pressed portion.

8. The chuck pin according to claim 1, further comprising:
a turning driving portion, configured to turn the holding portion and the fixing portion between a holding state, in which the substrate is held by abutting the outer circumferential surface of the holding portion against the substrate, and a non-holding state, in which the substrate is not held by separating the outer circumferential surface of the holding portion from the substrate.

9. A substrate holding device, comprising:
the chuck pin according to claim 1; and
a plate portion to which the fixing portion of the chuck pin is mounted.

10. The substrate holding device according to claim 9, further comprising a rotation driving portion configured to rotate the plate portion.

11. The substrate holding device according to claim 9, further comprising an arm portion configured to push the holding portion into the fixing portion while gripping the holding portion of the chuck pin.

12. The substrate holding device according to claim 9, further comprising an arm portion configured to twist the holding portion in a second rotation direction opposite to the first rotation direction and pull out the holding portion from the fixing portion while gripping the holding portion of the chuck pin.
